(19) United States
(12) Patent Application Publication
(10) Pub. No.: US 2007/0264770 A1
(43) Pub. Date: Nov. 15, 2007

(54) CAPACITOR FORMING METHOD

(75) Inventors: Keum Bum Lee, Icheon-si (KR); Hai Won Kim, Icheon-si (KR); Ho Jin Cho, Seoul (KR); Jun Soo Chang, Icheon-si (KR); Eun A. Lee, Seoul (KR); Dong Su Park, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Icheon-si (KR)

(21) Appl. No.: 11/618,796

(22) Filed: Dec. 30, 2006

(30) Foreign Application Priority Data
May 15, 2006 (KR) 2006-43595

(51) Int. Cl. H01L 21/8242; H01L 29/92

(52) U.S. Cl. 438/240; 438/396; 438/253

(57) ABSTRACT

A method for forming a capacitor includes forming a concave mold over a semiconductor substrate. A storage node is formed on the concave mold. A dielectric layer including a zirconium oxide (ZrO2) layer is deposited over the storage node at a first temperature. A radical pile-up treatment on the dielectric layer is performed in an atmosphere including radicals at a second temperature higher than the first temperature to induce crystallization of the dielectric layer. A plate node is formed over the dielectric layer.

### CROSS-REFERENCES TO RELATED APPLICATIONS

The present application claims priority to Korean patent application No. 10-2006-043595, field on May 15, 2006, which is incorporated by reference in its entirety.

### BACKGROUND OF THE INVENTION

The present invention relates to a semiconductor device, and, more particularly to a method for forming a capacitor that is capable of improving capacitance characteristics.

As the integration of semiconductor devices has increased, the design rule of semiconductor devices has been rapidly reduced to sub-80 nm. As a result, several attempts have been made to form a capacitor that is capable of achieving desired capacitance with a limited area in a dynamic random access memory (DRAM) device.

For example, a method of forming a dielectric layer of the capacitor using a dielectric material having a high dielectric constant [e.g., hafnium oxide (HfO₂) or aluminum oxide (Al₂O₃)]. The hafnium oxide or the aluminum oxide may be deposited by atomic layer deposition (ALD) to increase the capacitance of the capacitor. However, this attempt has also reached its limit.

In the case of the hafnium oxide, the process window margin may be insufficient for increasing the capacitance because it may be very difficult to carry out the process. Consequently, it is difficult to improve the electrical characteristics of the capacitor. In the case of a structure which uses aluminum oxide and hafnium oxide together [e.g., HfO₂/Al₂O₃/HfO₂ (HAH)], the improvement of the characteristics of the capacitor may also be limited. In the case of using such a hafnium oxide, the fluctuation of the electrical dielectric characteristics due to the crystallization of the hafnium oxide may restrict the attempt.

Consequently, it is highly desired to develop a capacitor that has improved capacitance and leakage current characteristics.

### SUMMARY OF THE INVENTION

Embodiments of the present invention are directed to a method for forming a capacitor that is capable of improving capacitance characteristics.

In accordance with one aspect of the present invention, a method for forming a capacitor includes the steps of; forming a mold layer having an opening hole on a semiconductor substrate; forming a storage node including a metal layer following the profile of the opening hole; depositing a dielectric layer including a zirconium oxide (ZrO₂) layer on the storage node; performing the radical pile-up treatment to the dielectric layer using an oxygen radical atmosphere for crystallization of the dielectric layer and performing the heat treatment at a temperature higher than the deposition temperature; and forming a plate node on the dielectric layer.

Preferably, the radical pile-up treatment is accompanied by the heat treatment of approximately 400 to 500° C.

Preferably, the radical atmosphere is formed with plasma radicals having a low energy of 1 eV/atom, at which the generation of plasma ions is substantially prevented.

Preferably, the dielectric layer, which includes a triple composite layer of a zirconium oxide layer, an aluminum oxide layer, and a zirconium oxide layer, is formed by atomic layer deposition.

Preferably, the atomic layer deposition is carried out at a temperature of approximately 250 to 350° C.

In accordance with another aspect of the present invention, a method for forming a capacitor includes the steps of: depositing a semiconductor substrate having a dielectric layer including a zirconium oxide (ZrO₂) layer deposited thereon on a storage node in a process chamber; generating an oxygen radical atmosphere by a radical generating unit connected to the process chamber; supplying the oxygen radical atmosphere into the process chamber and performing the heat treatment to the semiconductor substrate so as to perform the radical pile-up treatment at the surface of the dielectric layer and to perform the crystallization of the dielectric layer; and forming a plate node on the dielectric layer.

In yet another embodiment, a method for forming a capacitor includes forming a concave mold over a semiconductor substrate. A storage node is formed on the concave mold. A dielectric layer including a zirconium oxide (ZrO₂) layer is deposited over the storage node at a first temperature. A radical pile-up treatment on the dielectric layer is performed in an atmosphere including radicals at a second temperature higher than the first temperature to induce crystallization of the dielectric layer. A plate node is formed over the dielectric layer.

### BRIEF DESCRIPTION OF THE DRAWINGS

FIGS. 1 to 4 are sectional views illustrating a capacitor forming method according to the present invention; and

FIG. 5 is an illustration showing the radical treatment in the capacitor forming method according to the present invention.

### DESCRIPTION OF SPECIFIC EMBODIMENTS

The present invention provides a method of forming a capacitor using zirconium oxide (ZrO₂), instead of the more conventional hafnium oxide. With hafnium oxide the improvement of the leakage current characteristics may be difficult when a crystal grows due to the increase in the thickness of the hafnium oxide. The zirconium oxide (ZrO₂) can be advantageous in that the electrical characteristics are improved as crystallization increases, unlike the hafnium oxide.

The zirconium oxide (ZrO₂) may be deposited by atomic layer deposition (ALD) using a zirconium source, such as Zr[N(CH₃)]₄, Zr[N(CH₂CH₃)]₄, Zr[N(CH₃) (CH₂CH₃)]₄, or Zr[N(CH₃)₂(CH₂CH₃)₂]₄. The atomic layer deposition may also use an oxygen source, such as an ozone (O₃) gas, vapor (H₂O), or an oxygen (O₂) gas. Atomic layer deposition can be advantageous in that uniform-thickness deposition can be performed on a storage node having a three-dimensional structure such as a cylinder, as compared to chemical vapor deposition (CVD) which has different step coverage.

During the deposition of the zirconium oxide the temperature of the zirconium source may be set around 320° C. or more; however, heat decomposition occurs to the extent that the ALD deposition may not be carried out, but CVD deposition may still be carried out. With CVD deposition, the quantity of impurities, such as carbon, may be increased in the zirconium oxide layer, and the step coverage characteristics may be degraded. As a result, the leakage current may be increased. Thus, the ALD deposition is carried out at a temperature less than the heat decomposition degree of the zirconium source, i.e., at a temperature of no more than 350° C., preferably approximately 250 to 300° C.

When the zirconium oxide has a crystal polymorph of a complex structure of a monoclinic, tetragonal and cubic mixed structure, the zirconium oxide can have higher dielectric constant. The characteristics of the capacitor may be improved. For example, the increase of the capacitance and the decrease of the leakage current may be accomplished. However, it may be necessary to perform the heat treatment at a high temperature of at least 400° C. so as to accomplish this crystallization. In this case, the heat decomposition of the zirconium source, the degradation of the step coverage, and the increase of impurities, such as carbon, may occur.

The present embodiment provides a method for forming a capacitor where a zirconium oxide layer is deposited by ALD at a relatively low temperature, plasma having relatively low energy is generated in an oxygen and/or nitrogen radical atmosphere, and the surface treatment is performed to the zirconium oxide layer using the radical atmosphere at a temperature of at least 400° C.

The radical surface treatment increases the formation of the crystal polymorph in the zirconium oxide and derives the pile-up of the nitrogen or the oxygen at the surface (or the surface layer area) of the zirconium oxide layer. As a result, the leakage current characteristics of the zirconium oxide layer are improved by the surface treatment. The improvement of the break voltage (BV) due to low bias at the upper layer part of the device is accomplished by the pile-up of the nitrogen, or the oxygen, or the nitrogen and the oxygen.

The treatment using the oxygen or the nitrogen is accompanied by a process for heating the process chamber (or a substrate), such that the temperature of the process chamber of the substrate is maintained at approximately 400 to 500° C., in order to exclude the use of the heating effect due to the plasma, unlike the general plasma treatment.

Also, the generation of the oxygen or the nitrogen derives the generation of the plasma with relatively low energy (e.g., less than 1 eV/atom, unlike generation of the general plasma. According to circumstances, this plasma radical generation is carried out outside the process chamber. Preferably, plasma radicals are generated, and then the generated plasma radicals are introduced into the process chamber such that the surface treatment can be carried out by not the ionized plasma but the activated plasma.

The generation of the plasma ions may be restrained, and the generation of the activated radicals may be derived such that the surface treatment can be carried out by the activated radicals.

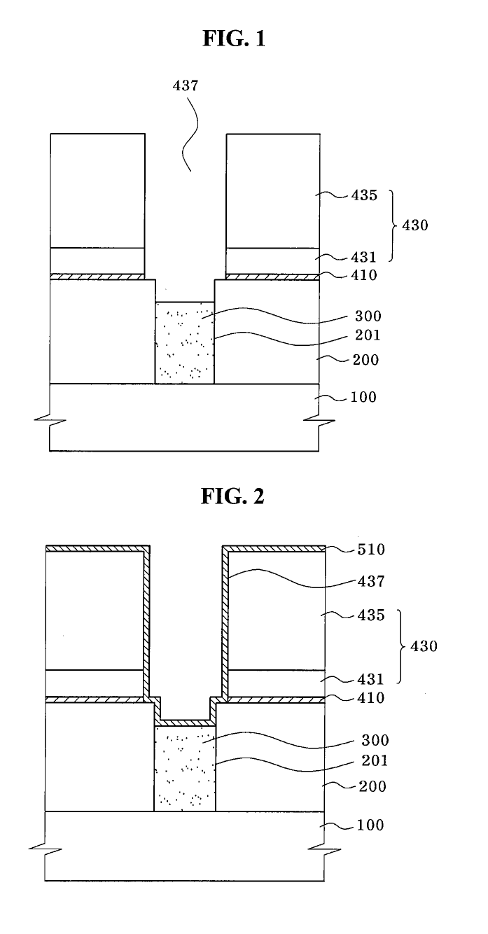

Referring to FIG. 1, an insulation layer 200 is formed on a semiconductor substrate 100, and a contact hole 201 is formed such that the contact hole 201 extends through the insulation layer 200. A conductive layer is formed, such that the contact hole 201 can be filled with the conductive layer, so as to form a storage node contact 300 to electrically connect a capacitor and a transistor device (not shown) formed on the semiconductor substrate 100 below the capacitor.

The storage node contact 300 may be formed by forming a conductive material layer, such as doped poly silicon, by chemical vapor deposition (CVD) and performing node separation through a flattening process, such as etch back.

Subsequently, an etch stop layer 410 is formed. The etch stop layer 410 is used as an etch termination point when a mold to shape a storage node having a three-dimensional structure, such as a cylinder, is formed on the storage node contact 300. The etch stop layer 410 may include a silicon nitride layer (Si₃N₄).

A mold layer 430 is formed on the etch stop layer 410. The mold layer 430 is for forming the storage node into a three-dimensional shape. The mold layer 430 may be made of an insulation material, such as silicon oxide. For example, the mold layer 430 may be formed by depositing a single layer of plasma enhanced tetra-ethyl-ortho-silicate glass (PE-TEOS) or a composite layer of phosphosilicate glass (PSG) and PETEOS.

To form the mold layer 430, a PSG layer is deposited to a thickness of approximately 8000 Å so as to form a first mold layer 431, and an undoped silicate glass (USG) layer, such as PETEOS, is deposited to a thickness of approximately 8000 Å so as to form a second mold layer 435. The mold layer 430 is formed by depositing the PSG and the USG at a ratio of approximately 1:2 to a thickness of at least 25000 Å. The thickness of the mold layer 430 may be set depending upon the height of the capacitor, especially, the height of the storage node.

Subsequently, a poly silicon layer (not shown), as a hard mask, is deposited to a thickness of at least 4000 Å on the mold layer 430. The mold layer 430 is selectively etched, using the hard mask as an etching mask, to form an opening hole 437. After that, a mold for a three-dimensional structure, such as a cylinder, will be used to form a storage node having a capacitor structure of metal-insulator-metal (MIM).

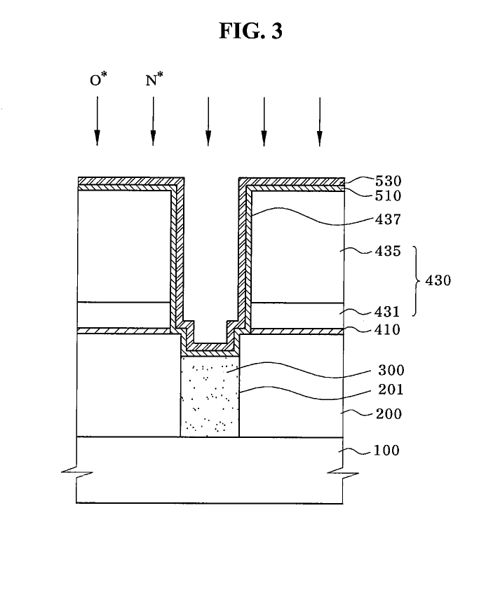

Referring to FIG. 2, a storage node 510, which is electrically connected to the storage node contact 300, is formed. For example, a conductive layer following the profile of the opening hole 437 is formed, and then node separation is performed using a flattening method, such as etch back or chemical mechanical polishing. In this way, one cylindrical storage node 510 is formed for each storage node contact 300.

The storage node 510 may be made of various conductive materials. The storage node 510 may be formed with a metal layer, such as a titanium nitride (TiN) layer, for the MIM structure. The TiN layer may be formed to a thickness of approximately 300 Å.

Referring to FIG. 3, a dielectric layer 530 following the profile of the storage node 510 is formed on the storage node 510. The dielectric layer 530 may be formed including a zirconium oxide layer. At this time, the zirconium oxide layer is deposited by ALD such that the zirconium oxide layer is formed along the profile of the storage node 510 while the zirconium oxide layer has good step coverage. In the ALD deposition, precursors having an organic ligand R coupled to a zirconium metal atom, such as Zr[N(CH₃)]₄, Zr[N(CH₂CH₃)]₄, Zr[N(CH₃) (CH₂CH₃)]₄, or Zr[N(CH₃)₂(CH₂CH₃)₂]₄, may be used as a zirconium source.

The precursors may be thermally decomposed at a considerably high temperature, for example, at a temperature higher than approximately 350° C. When the zirconium source is thermally decomposed, a CVDprocess may be unfortunately carried out. In order to prevent this problem, the deposition is performed at a temperature lower than the above-specified temperature, for example, at a temperature of approximately 250 to 350° C., preferably, at approximately 270° C. to 350° C. When the zirconium oxide is deposited by the ALD at the above-specified low deposition temperature, however, relatively low crystallization occurs, making it difficult to obtain the required higher dielectric constant.

In another embodiment of the present invention, an additional process is performed to improve the crystallization of the dielectric layer 530 including the zirconium oxide layer.

The dielectric layer 530 may be formed as a single zirconium oxide layer having a thickness of approximately 100 Å. In order to provide higher capacitance and improve the leakage current characteristics, the dielectric layer 530 may be formed as a composite layer, such as a triple layer including an aluminum oxide layer and a zirconium oxide layer. In this case, the leakage current characteristics may be improved by a laminate structure of Al₂O₃/ZrO₂.

The deposition of the composite layer may be carried out according to an ex-situ process in which the ALD processes of the respective layers are performed in different process chambers. However, to improve mass productivity the ALD processes of ZrO₂/Al₂O₃/ZrO₂ are sequentially performed in the same process chamber according to an in-situ process. In the present implementation, the ZrO₂/Al₂O₃/ZrO₂ layers may be formed to thicknesses of approximately 45/5/45 Å.

In the present implementation, Al (CH₃)₃ may be used as the aluminum source. Also, an ozone gas or vapor (H₂O) may be used as the oxygen source necessary for the ALD deposition of the zirconium oxide and the ALD deposition of the aluminum oxide.

In this case, the process is performed at a low temperature at which the heat decomposition of the zirconium source is prevented, for example, at a temperature of approximately 270° C. When the zirconium oxide is deposited by the ALD at the low deposition temperature, however, relatively low crystallization is accomplished, and therefore, it is difficult to obtain the required higher dielectric constant. Therefore, an additional process is performed to improve the crystallization of the dielectric layer 530.

Specifically, the surface of the dielectric layer 540 is treated using oxygen and/or nitrogen radicals (O* and/or N*). The oxygen and/or nitrogen radicals may be generated by a method of generating plasma having relatively low energy. As shown in FIG. 5, for example, the substrate 100 is mounted on a substrate mounting part 630 in the process chamber 610, and then radicals generated from a radical generating unit 650 are introduced onto the substrate 100.

The radical generating unit 650 generates plasma with relatively low energy (e.g. less than 1 eV/atom), unlike generation of the general plasma. However, the generation of plasma having low energy may be carried out in the process chamber 610 without using the radical generating unit 650 such that the activated plasma becomes relatively predominant.

An oxygen gas or vapor may be used as a radical source gas for the oxygen radicals. Nitrogen (N₂) gas, a nitrous oxide (N₂O) gas, a nitric oxide (NO) gas, or a nitrogen tri-hydride (NH₃) gas may be used as a radical source gas for the nitrogen radicals. When the oxygen radicals and the nitrogen radicals are introduced together, the nitric oxide gas may be used as the radical source gas.

After the plasma radicals are generated as described above, the radicals are introduced into the chamber 610 (see FIG. 5) such that the surface treatment is carried out using the activated radicals, not the ionized radicals. At this time, the substrate 100 is heated to a temperature of approximately 400 to 500° C. by a heater included in the substrate mounting part 630. The growth of crystal polymorph of the zirconium oxide is derived by heat energy generated at this temperature. At this time, oxygen is supplied into the zirconium from the oxygen radicals such that the increase of the crystallization is further accelerated. The temperature is kept below 500° C. so as to restrain excessive phase change in the present implementation.

By the radical surface treatment, the formation of the crystal polymorph in the zirconium oxide is increased, and the pile-up of nitrogen and/or oxygen at the surface (or the surface layer area) of the zirconium oxide layer is derived. The pile-up of the radicals may be accomplished at an area having a thickness of approximately 10 to 15 Å from the surface of the dielectric layer 530.

By the surface treatment, the leakage current characteristics of the zirconium oxide layer are improved. Especially, the improvement of the break voltage (BV) due to low bias at the upper layer part of the device is accomplished by the pile-up of the nitrogen and/or the oxygen.

In the case of a ZrO₂/Al₂O₃/ZrO₂ (ZAZ) structure, the capacitance is increased by more than approximately 2 fF/cell by the oxygen radical treatment accompanied by the heat treatment as compared to the capacitance before the treatment. Also, the leakage current is reduced from 0.13 fF/cell to 0.09 fF/cell. In other words, the leakage current characteristics are improved together with the increase of the capacitance.

In addition, the voltage drop due to the negative bias of the plate node, to be introduced onto the dielectric layer 530, is reduced from over 1 V to less than 0.5 V as compared with the positive bias of the plate node. In other words, the break voltage characteristics are further improved.

The improvement of the leakage current characteristics and the voltage characteristics are accomplished by the radical surface treatment. Specifically, the improvement of the leakage current characteristics and the voltage characteristics are accomplished by the prevention of ion bombardment effects due to the ionized plasma or sputtering heating. In addition, the improvement of the leakage current characteristics and the voltage characteristics are accomplished through the improvement of the electrical characteristics due to the pile-up of the oxygen and/or the nitrogen.

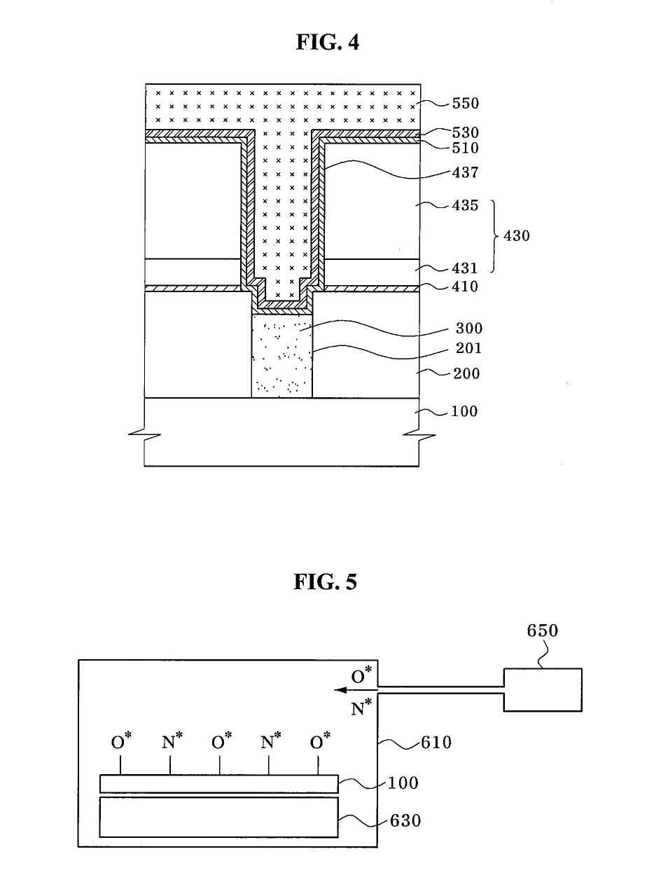

Referring to FIG. 4, a plate node 550 is formed on the dielectric layer 530 so as to complete a capacitor. The plate node 550 may be formed by depositing titanium nitride (TiN) to a thickness of approximately 300 Å at a temperature of approximately 500° C. or more. In this way, it is possible to manufacture a capacitor having the MIM structure.

Although the formation of the mold layer 430 as an intermediate insulation layer was illustrated in the above description, the mold layer 430 may be selectively removed such that the dielectric layer 530 extends to the outer side of the storage node 510.

As apparent from the above description, the dielectric layer of the capacitor is formed such that the dielectric layer includes the zirconium oxide, and the surface treatment is carried out using the oxygen and/or the nitrogen radicals, while the surface treatment is accompanied by the heat treatment of approximately 400° C., such that the zirconium oxide is constructed in the crystal polymorph structure, and therefore, the zirconium oxide has high dielectric constant. Furthermore, it is possible to improve the leakage current characteristics and the break voltage (BV) due to low bias at the upper layer part of the device through the nitrogen and/or the oxygen pile-up at the upper layer part of the zirconium oxide

The embodiments of the present invention have been disclosed for illustrative purposes. Those skilled in the art will appreciate that various modifications, additions and substitutions are possible, without departing from the scope and spirit of the invention as disclosed in the accompanying claims.

What is claimed is:

1. A method for forming a capacitor, the method comprising: forming a concave mold over a semiconductor substrate;
forming a storage node over the concave mold
depositing a dielectric layer including a zirconium oxide (ZrO₂) layer over the storage node at a first temperature;
performing a radical pile-up treatment on the dielectric layer in an atmosphere including radicals at a second temperature higher than the first temperature to induce crystallization of the dielectric layer; and
forming a plate node over the dielectric layer.

2. The method according to claim 1, wherein the second temperature is between 400 to 500° C.

3. The method according to claim 1, wherein the radical atmosphere is formed with plasma radicals having a low energy at which the generation of plasma ions is substantially prevented.

4. The method according to claim 1, wherein the atmosphere includes oxygen radicals.

5. The method according to claim 1, wherein the atmosphere includes nitrogen radicals.

6. The method according to claim 5, wherein the radical atmosphere is generated using a nitric oxide (NO) gas as a source gas for the generation of the oxygen and nitrogen radicals.

7. The method according to claim 1, wherein the dielectric layer is formed by atomic layer deposition at a temperature of approximately 250 to 350° C.

8. The method according to claim 1, wherein the dielectric layer is formed by atomic layer deposition at a temperature of approximately 270° C.

9. The method according to claim 1, wherein the dielectric layer includes a first zirconium oxide layer, an aluminum oxide layer, and a second zirconium oxide layer.

10. The method according to claim 9, wherein the atomic layer depositions are carried out in an in-situ process at a temperature of approximately 250 to 320° C.

11. The method according to claim 1, wherein the storage node includes a titanium nitride layer.

12. The method according to claim 1, wherein the plate node includes a titanium nitride layer.

13. A capacitor forming method comprising:
loading a semiconductor substrate having a dielectric layer including a zirconium oxide (ZrO₂) layer deposited on a storage node in a process chamber;
generating oxygen radicals in a radical generating part connected to the process chamber;
supplying the oxygen radicals into the process chamber;
performing a heat treatment to the semiconductor substrate to perform a radical pile-up treatment on a surface of the dielectric layer and induce crystallization of the dielectric layer; and
forming a plate node over the dielectric layer.

14. The method according to claiml3, wherein the dielectric layer is formed by atomic layer deposition at a temperature between 250 to 350° C.

15. The method according to claim 14, wherein the heat treatment is performed at a temperature between 400 to 500° C.

16. The method according to claim 13, wherein the radicals are formed with plasma radicals having a low energy at which the generation of plasma ions is substantially prevented.

17. The method according to claim 13, wherein nitrogen radicals are supplied into the process chamber, so that the heat treatment is performed in an atmosphere including the oxygen and nitrogen radicals.

18. The method according to claim 17, wherein the radical atmosphere is generated using a nitric oxide (NO) gas as a source gas for the generation of the oxygen and nitrogen radicals.

19. The method according to claim 13, wherein the dielectric layer is formed by sequentially depositing a first zirconium oxide layer, an aluminum oxide layer, and a second zirconium oxide layer.

20. The method according to claim 19, wherein the first zirconium oxide layer, the aluminum oxide layer, and the second zirconium oxide layer are formed in an in-situ process at a temperature between 250 to 350° C.
